(19) United States
(12) Patent Application Publication
(10) Pub. No.: US 2017/0284647 A1
(43) Pub. Date: Oct. 5, 2017

(54) FLEXIBLE INTERCONNECTION BETWEEN SUBSTRATES AND A MULTI-DIMENSIONAL LIGHT ENGINE USING THE SAME

(71) Applicants: Alfredo Morin, San Nicolas (MX); Jesus Godina, Apodaca (MX); Valeriy Zolotykh, Abington, MA (US); Anil Jeswani, Acton, MA (US); Ming Li, Acton, MA (US)

(72) Inventors: Alfredo Morin, San Nicolas (MX); Jesus Godina, Apodaca (MX); Valeriy Zolotykh, Abington, MA (US); Anil Jeswani, Acton, MA (US); Ming Li, Acton, MA (US)

(73) Assignee: OSRAM SYLVANIA Inc., Wilmington, MA (US)

(21) Appl. No.: 15/087,834

(22) Filed: Mar. 31, 2016

(51) Int. Cl. F21V 23/06; F21K 99/00; F21V 19/00; H05K 1/14; F21V 29/70

(52) U.S. Cl. CPC F21V 23/06; H05K 1/14; F21V 29/70; F21V 19/003; F21K 9/1355; H05K 2201/10113; F21Y 2111/001

(57) ABSTRACT

Flexible interconnection between substrates, where the substrates include one or more solid state light sources, mounted at varying angles are provided. A multi-dimensional lighting device is formed using such substrates. The multi-dimensional lighting device includes external mounting surfaces, each configured to provide mounting positions for one or more substrates. A flexible jumper device electrically couples a given substrate to an adjacent substrate, and provides a predefined clearance between surfaces of the same and exposed conductive surfaces of the lighting device. Each flexible jumper includes a surface mount device (SMD) capable of being placed by automated process, such as by pick-and-place machines. Such lighting devices are thus possible using automated processes in a high-volume, highly-precise manner.

### TECHNICAL FIELD

The present invention relates to lighting, and more specifically, to surface mount jumpers coupling substrates for lighting devices.

### BACKGROUND

Solid state lighting technology continues to increase in efficiency and capabilities, and have become a viable alternative to traditional incandescent and fluorescent technology in many general lighting applications. For example, lighting devices including one or more solid state light sources, such as but not limited to light emitting diodes (LEDs), organic light emitting diodes (OLEDs), polymer light emitting diodes (PLEDs), organic light emitting compounds (OLECs), laser diodes, and the like, generally provide longer operational lifespans than traditional lighting technologies, high-energy efficiency, compactness, and reliability.

### SUMMARY

One issue facing increased adoption of solid state lighting devices is their directional lighting characteristics. For instance, solid state lighting devices generally deliver directional light, also known as a forward or forward light cone. However, under some standards, such as the luminous flux measurement (“LM”) 79 specifications, lighting fixtures are required to deliver omnidirectional light. Thus numerous non-trivial issues arise in the design and manufacture of omnidirectional lighting devices.

One type of conventional omnidirectional solid state lighting devices includes mounting one or more solid state light sources to a single, planar surface of the lighting device, and using some combination of reflectors, diffusers, lenses, and/or other optical components to emit light in a manner that approximates omnidirectional illumination. However, solid state light sources produce directional light, and a lighting device having such a single-dimension or single-plane of illumination at best mimics a hemispherical light pattern of, for example, an incandescent lamp. This mimicking has drawbacks, such as attenuated output light and an uneven intensity of an output light pattern in each direction. Further, solid state lighting devices configured in this manner may produce illumination with a perceivable effect known as “shadowing.”

Another type of conventional omnidirectional solid state lighting devices includes mounting solid state light sources to a plurality of mounting surfaces, with each mounting surface being angled in a manner that allows the mounted solid state light sources to uniformly produce light in all directions around the lighting device. Lighting devices configured in this manner may be accurately referred to as three-dimensional, or multi-dimensional. While three-dimensional solid state lighting devices can produce substantially omnidirectional illumination, such devices are relatively more complex and expensive to manufacture than a single-dimensional solid state lighting device. For example, some manufacturing processes for producing three-dimensional solid state lighting devices use printed circuit board (PCB) panelization techniques, whereby a number of PCB boards or other substrates are populated using automated pick-and-place machines to deposit electrical components and associated circuitry. Once populated, the individual boards may be singulated, e.g., cut or otherwise mechanically separated from the PCB panel, and then mounted manually by a technician to mounting surfaces of the lighting device. In some cases, the mounting surfaces of the lighting device are provided by a heatsink member configured to assist in dissipating heat from the PCB boards. Once the PCB boards get mounted to the mounting surfaces of the lighting device, the technician may electrically couple the PCB boards into a circuit using, for example, an insulated wire or ribbon cable using a soldering or welding technique. To this end, each lighting device requires a considerable amount of time to complete, as a technician must affix each individual PCB and then ensure each is properly soldered, such that a circuit is formed and can deliver power to each of the solid state light sources when the three-dimensional lighting device receives power and is supposed to emit light.

Embodiments provide for a three-dimensional lighting device that includes using flexible jumper devices, such as surface mount device (SMD) jumpers, to electrically couple substrates including one or more solid state light sources to form a light engine circuit. SMD jumpers are particularly well suited for placement using surface mount technology (SMT) component placement systems, such as pick-and-place machines. The flexible jumper devices can be deposited onto substrates, such as PCBs, in an automated fashion prior to singulation and fixation to a lighting device. Such a light engine circuit may be entirely formed using an automated process which, in some embodiments, reduces overall costs, increases reliability, and reduces the overall complexity and time spent during post-automated stages, such as those described above.

In some embodiments, a three-dimensional lighting device includes a body or housing, with the housing including a base portion, a heatsink portion, and in some embodiments, an optical system such as but not limited to a lens. The power coupling end or mounting end, in some embodiments, is configured with a threaded coupling member or other connector type configured to electrically couple the three-dimensional lighting device into a lighting socket or fixture. A power supply circuit, in some embodiments, is disposed within the housing and configured to convert AC power from an external source to DC for the purposes of providing power to the solid state light source(s) when lit. Alternatively, or in addition to providing DC power, in some embodiments, the power supply circuit provides AC power. A plurality of substrates, such as but not limited to a printed circuit board, and at least one solid state light source, is fixedly attached to a plurality of external mounting surfaces provided by the heatsink member. In some embodiments, a substrate includes a metal core PCB (MCPCB) having a core of aluminum or copper, for example. However, numerous other PCB types and substrates are also applicable and are within the scope of this disclosure.

The substrates, in some embodiments, are electrically coupled to form a light engine circuit, with a flexible jumper that electrically couples one substrate to an adjacent substrate. As should be appreciated, the light engine circuit can and in some embodiments does include a series circuit configuration, a parallel circuit configuration, or a combination of both configurations, depending on a desired configuration. The light engine circuit in some embodiments is electrically coupled to the power supply circuit based on a first substrate being electrically coupled to a positive or negative lead of the power supply circuit, and a last substrate coupled to the other of the positive or negative lead. Thus, in some embodiments, the light engine circuit “wraps” around the heatsink member and conforms to the contours of the external mounting surfaces by allowing each substrate to be disposed at an angle different than adjacent substrates. The ability of the light engine circuit to conform in this manner may be accurately described as “flex,” and may be enabled at least in part by the flexible jumper devices that electrically couple each of the substrates and can bend to allow for a relatively large difference (e.g., up to about 180 degrees or more) between the angles of two interconnected substrates.

In some embodiments, the flexible jumpers comprise surface mount device (SMD) jumpers. The SMD jumpers are formed with a generally omega (Q) shape or configuration, although other shapes and geometries will be apparent in light of this disclosure. As referred to herein, an omega shape does not necessarily refer to an exact omega shape and instead refers to any jumper shape that can provide one or more arcuate regions designed to extend between and interconnect two substrates, and project outwardly from the same such that predefined clearance is provided between the jumper and exposed conductive surfaces of the lighting device. Moreover, numerous other shapes will be apparent in light of this disclosure and may be suitable for use in aspects and embodiment disclosed herein. For example, one such example shape is shown in FIG. 7 and includes a double-bend configuration. As will be appreciated, SMD jumpers are SMT-compatible components whereby SMT component placement systems, e.g., pick-and-place machines, can automate placement and welding on to respective substrates. The SMD jumpers may, and in some embodiments do, comprise any suitable conductive material capable of electrically coupling adjacent substrates. The SMD jumpers, in some embodiments, are formed from, for example, steel, copper, tin, nickel, or any alloy thereof. In addition, the SMD jumpers in some embodiments comprise multiple layers including a base layer, and a coating layer, for example. In some such embodiments, the base layer is formed from a first material and the coating layer is formed from a second material, with the first material being different from the second. In any event, the particular material(s) and thicknesses chosen for the SMD jumpers, in some embodiments, is based on a desired rigidity/elasticity. For example, in some embodiments, the SMD jumpers may exert spring-like bias onto the substrates which they are mounted on. Thus, the particular materials chosen may be optimized such that the spring-like bias does not displace or otherwise overcome the force of glue, tape, or other adhesive holding the substrates at a fixed position on the heatsink member or other mounting surface. On the other hand, particular materials are selected in some embodiments in order to provide an SMD jumper that does not permanently deform based on a force exerted by a technician when handling and mounting the light engine circuit to the three-dimensional lighting device. In some embodiments, the SMD jumpers are formed from a copper-nickel alloy having a hardness of H½. In some such embodiments, the SMD jumper includes an overall length of about 8.0 mm, an overall height of about 3.5 mm, and a thickness, such as but not limited to about 0.30 mm.

As should be appreciated, some flexible jumper devices such as SMD jumpers feature so-called “bare metal” contacts. Some lighting standards require that exposed conductive surfaces be no closer than a predefined distance to avoid shorts/arcs and other electrical interference, with the predefined distance or creepage distance being relative to the RMS working voltage for the lighting device. Thus, some embodiments include flexible jumpers configured with geometries that provide sufficient clearance between conductive surfaces of the same and exposed conductive surfaces of the three-dimensional lighting device, such as surfaces of the heatsink member and a metal core PCB, for example. Moreover, in some embodiments, the flexible jumpers allow substrates to be spaced within a predefined range of acceptable deviation, e.g., about ±1 mm or more depending on a desired configuration, without causing the flexible jumpers to provide insufficient clearance and be outside of tolerance. The heatsink member, or other such mounting surface, in some embodiments, includes guides or stops designed to align substrates into a proper position during manufacturing, and prevents longitudinal and/or lateral movement to ensure the flexible jumpers remain within tolerance.

In an embodiment, there is provided a method of forming a lighting device. The method includes: populating a substrate panel with a plurality of solid state light sources, wherein the substrate panel comprises a plurality of substrates configured to be de-panelized and collectively form a light engine circuit; depositing a plurality of surface mount device (SMD) jumpers on the substrate panel to electrically couple at least two substrates of the plurality of substrates; de-paneling the at least two substrates from the substrate panel to form the light engine circuit; and mounting the light engine circuit to a body portion of the lighting device by coupling the at least two substrates of the plurality of substrates to respective external mounting surfaces of the body portion.

In a related embodiment, depositing may include depositing a plurality of surface mount device (SMD) jumpers on the substrate panel to electrically couple at least two substrates of the plurality of substrates, each of the at least two substrates may include a printed circuit board including a metal core. In another related embodiment, depositing may include depositing a plurality of surface mount device (SMD) jumpers on the substrate panel to electrically couple at least two substrates of the plurality of substrates, the plurality of SMD jumpers may include an alloy. In still another related embodiment, depositing may include depositing a plurality of surface mount device (SMD) jumpers on the substrate panel to electrically couple at least two substrates of the plurality of substrates, the plurality of SMD jumpers may include a generally omega shape. In yet another related embodiment, depositing the plurality of SMD jumpers may further include using a surface mount technology (SMT) component placement system.

In still yet another related embodiment, mounting the light engine circuit to a body portion may include mounting the light engine circuit to a body portion of the lighting device by coupling the at least two substrates of the plurality of substrates to respective external mounting surfaces of the body portion, the body portion of the lighting device may include a heatsink member, and the mounting surfaces may include at least three vertical mounting surfaces defined by the heatsink member.

In yet still another related embodiment, mounting the light engine circuit to the body portion of the lighting device may include coupling the at least two substrates at differing angles, the differing angles causing each SMD jumper to bend to accommodate a difference in angles between adjacent substrates, and each SMD jumper may extend from the body portion of the lighting device to provide a clearance distance between surfaces of each SMD jumper and any exposed conductive surface of the lighting device. In a further related embodiment, mounting the light engine circuit to the body portion of the lighting device may include coupling the at least two substrates at differing angles, the differing angles causing each SMD jumper to bend to accommodate a difference in angles between adjacent substrates, and each SMD jumper may extend from the body portion of the lighting device to provide a clearance distance between surfaces of each SMD jumper and any exposed conductive surface of the lighting device, and the clearance distance may be at least 0.6 mm.

In still yet another related embodiment, mounting the light engine circuit may further include using mechanical stops provided by the body portion to align each substrate of the at least two substrates.

In another embodiment, there is provided a lighting device. The lighting device includes: a body portion providing a plurality of external mounting surfaces; and a plurality of substrates with at least one substrates coupled to each of the plurality of external mounting surfaces, each substrate comprising a solid state light source; wherein each substrate is electrically coupled to an adjacent substrate via a surface mount device (SMD) jumper that provides electrical conductivity between each substrate and the adjacent substrate.

In a related embodiment, the body portion may include a heatsink member and the plurality of external mounting surfaces may be provided by the heatsink member. In another related embodiment, each of the plurality of printed circuit boards may include a printed circuit board including a metal core. In yet another related embodiment, each SMD jumper may include an alloy. In still another related embodiment, each SMD jumper may include a generally omega shape.

In yet still another related embodiment, each of the SMD jumpers may provide a predefined clearance between surfaces of the SMD jumpers and any exposed conductive surface of the lighting device. In a further related embodiment, the predefined clearance may be at least 0.6 mm, and the exposed conductive surface of the lighting device may include a surface of a metal heatsink member.

In still yet another related embodiment, each SMD jumper may include a plurality of arcuate regions configured to extend conductive surfaces of each SMD jumper away from exposed conductive surfaces of the lighting device. In yet still another embodiment, each of the plurality of substrates may be electrically coupled in series.

In another embodiment, there is provided a lighting device. The lighting device includes: a body portion comprising a heatsink member, the heatsink member providing a plurality of external mounting surfaces, the plurality of external mounting surfaces including at least three vertical mounting surfaces that extend to a top mounting surface; and a plurality of substrates, each substrate comprising a solid state light source, wherein at least one substrate of the plurality of substrates is coupled to each of the plurality of external mounting surfaces; wherein each substrate is electrically coupled to an adjacent substrate via a surface mount device (SMD) jumper that provides electrical conductivity between each substrate and the adjacent substrate.

In a related embodiment, each SMD jumper may extend away from any exposed conductive surface of the lighting device by a clearance distance. In a further related embodiment, the clearance distance may be at least 1.4 mm.

### BRIEF DESCRIPTION OF THE DRAWINGS

The foregoing and other objects, features and advantages disclosed herein will be apparent from the following description of particular embodiments disclosed herein, as illustrated in the accompanying drawings in which like reference characters refer to the same parts throughout the different views. The drawings are not necessarily to scale, emphasis instead being placed upon illustrating the principles disclosed herein.

FIG. 1 shows a three-dimensional lighting device according to embodiments disclosed herein.

FIG. 2A shows a perspective view of an enlarged portion of the three-dimensional lighting device of FIG. 1 with a lens member removed, according to embodiments disclosed herein.

FIG. 2B shows an elevation view of the three-dimensional lighting device of FIG. 1 with a lens member removed, according to embodiments disclosed herein.

FIG. 3 illustrates a plan view of a flexible jumper device suitable for use in the three-dimensional lighting device of FIG. 1, according to embodiments disclosed herein.

FIG. 4 is top-down perspective view of the three-dimensional lighting device of FIG. 1, according to embodiments disclosed herein.

FIGS. 5-6 each show additional top-down perspective views of the three-dimensional lighting device of FIG. 1, according to embodiments disclosed herein.

FIG. 7 shows an additional top-down perspective view of the three-dimensional lighting device of FIG. 1 and another flexible jumper device suitable for use within the same, according to embodiments disclosed herein.

FIG. 8 shows a method of forming the three-dimensional lighting device of FIG. 1, according to embodiments disclosed herein.

FIGS. 9-12 each show various stages of a light engine circuit formed from a substrate panel during performance of the method of FIG. 8, according to embodiments disclosed herein.

### DETAILED DESCRIPTION

Embodiments disclose techniques that use flexible jumper devices to electrically couple substrates including one or more solid state light sources within a three-dimensional lighting device. The three-dimensional lighting device, in some embodiments, includes a body portion that defines a plurality of vertical external mounting surfaces that extend to at least one horizontal or top mounting surface. Each mounting surface, in some embodiments, is configured to provide mounting positions for one or more substrates. Each substrate, in some embodiments, includes a printed circuit board, one or more solid state light sources (such as but not limited to LED packages), and associated circuitry. A flexible jumper device electrically couples a given substrate to an adjacent substrate. The electrically coupled substrates are disposed on the external mounting surfaces of the three-dimensional lighting device such that they “wrap” around the same. To this end, substrates in some embodiments are vertically mounted and face different directions so that their respective forward light cones illuminate different regions of a given area with a generally uniform amount of light at each angle. In addition, in some embodiments, at least one substrate is horizontally mounted to the top surface of the three-dimensional lighting device. Thus, in some embodiments, the three-dimensional lighting device provides substantially omnidirectional illumination with minimized or otherwise reduced shadowing effect.

The flexible jumpers, in some embodiments, include geometries that allow for a predefined clearance, e.g., so-called “creepage” distances, to be maintained between surfaces of the same and exposed conductive surfaces the three-dimensional lighting device in order to prevent electrical shorts/arcs or other interference during operation. The flexible jumper devices, in some embodiments, include surface mount devices (SMD) capable of being precisely placed by automated process equipment such as by surface mount technology (SMT) component placement systems, generally referred to as pick-and-place machines. Thus, some embodiments disclosed herein enable automated manufacturing processes to form a substantial portion of a three-dimensional lighting device in a high-volume, highly-precise manner, which may be relatively less expensive and provide greater reliability over other manufacturing approaches.

Substrates electrically coupled by one or more flexible jumper devices are sometimes referred to throughout as a light engine circuit. Some embodiments are accurately described as a three-dimensional light engine or a multi-dimensional light engine. As should be appreciated, the term three-dimensional used throughout generally refers to the shape/geometries of the mounting portions of a lighting device, e.g., the external mounting surfaces, which can allow one or more solid state light sources to be mounted vertically or horizontally, or both, and at various differing angles. By way of contrast, so-called “single-dimension” lighting devices generally include a single planar horizontal mounting surface with one or more solid state light sources mounted thereon. Thus, the term “three-dimensional” does not necessarily refer to an exact number of dimensions and instead refers generally to a shape that allows lighting assemblies to be mounted in a multi-dimensional fashion rather than in a single-dimensional mounting arrangement.

The term omnidirectional, as generally referred to herein, refers to a generally uniform light pattern output in all directions. In a more technical sense, omnidirectional may refer to an even distribution of luminous intensity as determined by, for example, the ENERGY STAR Program Requirements for Lamps (Light Bulbs) published in 2016, which prescribes the luminous intensity distribution of omnidirectional LED lamp (also called as non-directional lamp). The ENERGY STAR standard includes a prescribed measurement pattern including luminous intensity measurements repeated in vertical planes about the lamp (polar) axis in maximum increments of 22.5° from 0° to 180°. In addition, luminous intensity is measured within each vertical plane at a 5° vertical angle increment from 0° degrees to 180°. Of the measured luminous intensity values, 80% may vary by no more than 35% from the average of all measured values in all planes in the 0° to 130° zone. All measured values (candelas) in the 0° to 130° zone shall vary by no more than 60% from the average of all measured values in that zone. Further, at least 5% of total flux (lm) should be produced in the 130° to 180° zone.

The term “coupled” as used herein refers to any connection, coupling, link or the like and “electrically coupled” refers to coupling such that power from one element is imparted to another element. Such “coupled” devices are not necessarily directly connected to one another and may be separated by intermediate components or devices that may manipulate or modify such signals.

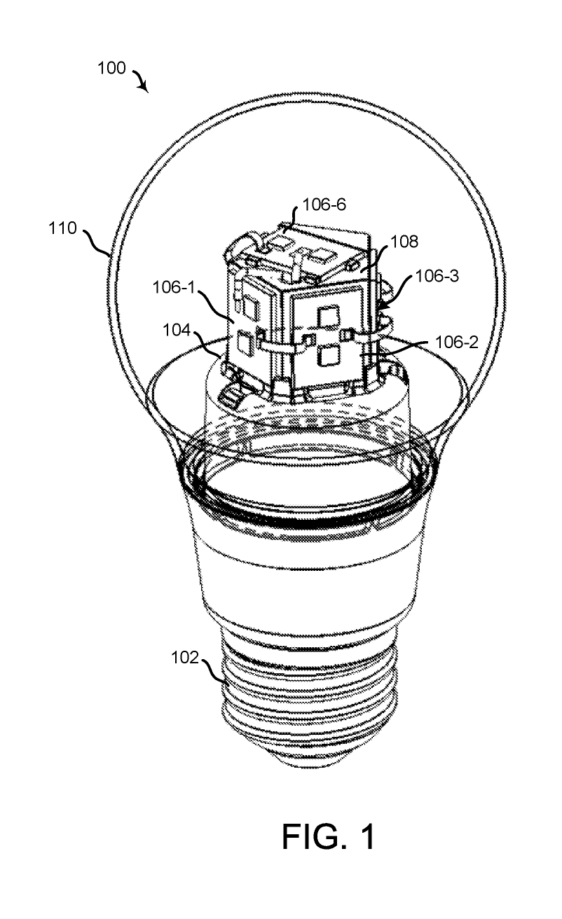

FIG. 1 illustrates a lighting device 100. The lighting device 100 includes a coupling member 102, a base member 104, a heatsink member 108, a plurality of substrates 106-1, 106-2, . . . , 106-6, and an optical system 110. As shown, the coupling member 102 includes a threaded base configured to couple with a conventional lighting or lamp socket. The lamp socket, not shown in FIG. 1, provides power to the lighting device 100. The lighting device 100, in some embodiments, uses other types of mounting mechanisms such as, for example, a bayonet coupling or other suitable mechanisms configured to electrically couple the lighting device 100 to a lighting socket or fixture. It should be noted that the lighting device 100, in some embodiments, is implemented in other configurations and thus is not necessarily limited to the particular configuration illustrated in FIG. 1.

The heatsink member 108 includes a metal such as but not limited to, for example, aluminum, copper, nickel, silver, zinc, or any alloy thereof. The heatsink member 108, in some embodiments, includes in whole or in part, another thermoconductive material, such as a polymer or graphite, for example. The base member 104 and the heatsink member 108, in some embodiments, are separate members, and in some embodiments, are a single member, depending on a desired configuration. In some embodiments, the base member 104 and the heatsink member 108 are formed from a same or substantially similar material such that there is similar thermal conductivity characteristics and low thermal resistance. In any event, the base member 104 and the heatsink member 108 are also collectively referred to as a body portion 104, 108.

In some embodiments, the base member 104 is configured as a mount that allows the heat sink member 108 to be supported. In some embodiments, the base member 104 and the heatsink member 108 include a cavity (not shown) that allows wires and/or other associated circuitry to be disposed therein and couples the plurality of substrates 106-1, 106-2, . . . , 106-6 to the coupling member 102, such that when the lighting device 100 is “lit”, each of the plurality of substrates 106-1, 106-2, . . . 106-6 draws power for illumination purposes. Thus, the wires and associated circuitry are understood to be a power supply circuit. The power supply circuit is configured to receive AC power via the coupling member 102 and to provide the same as DC power to the plurality of substrates 106-1, 106-2, . . . , 106-6. Alternatively, or in addition to providing DC power, the power supply circuit in some embodiments is configured to provide AC power, or a combination of AC and DC power. Thus, in some embodiments, the power supply circuit includes, for example, rectifiers, diodes, capacitors, transistors, integrated circuits (ICs), and/or any other suitable components.

The optical system 110 encloses the base member 104 and the heatsink member 108. The optical system 110 is, in some embodiments, made of plastic, glass, polymer, composite, or any other suitable material. The optical system 110, in some embodiments, is transparent or semi-transparent (e.g., milky white or white color). In some embodiments, the optical system 110 includes a coating that provides the transparent or semi-transparent properties. In any event, the optical system 110, in some embodiments, is configured to facilitate redistribution of light from directional radiation to omnidirectional radiation.

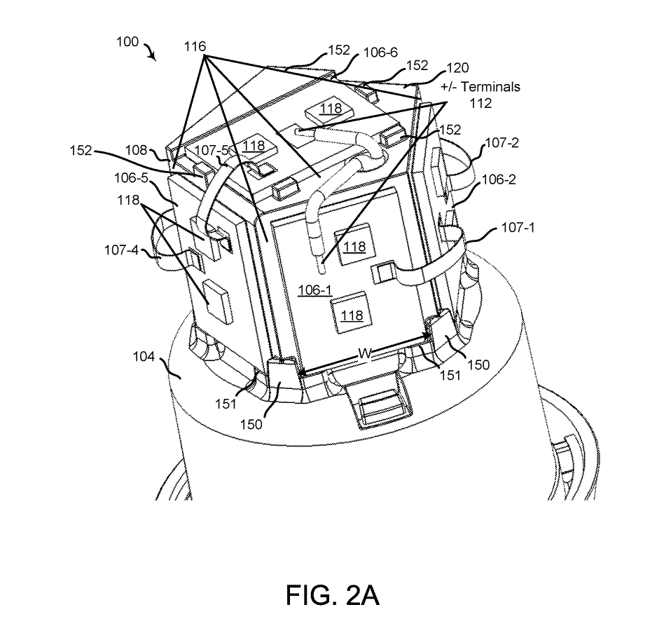

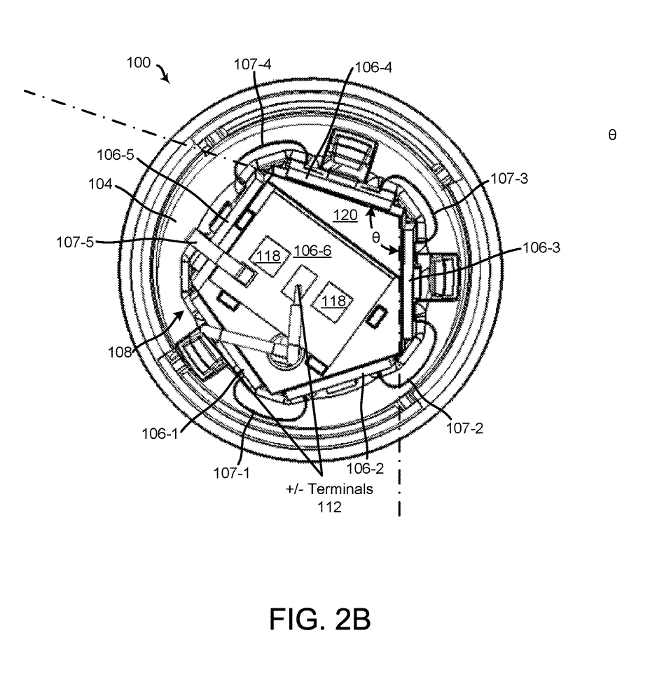

FIG. 2A shows an enlarged perspective view of the heatsink member 108 of FIG. 1 with the optical system 110 removed. In some embodiments, the heatsink member 108 is fabricated as a cylindrical column, square tube, hexagon tube, octagon shape, or other shape depending on desired configuration. The heatsink member 108 supports one or more substrates in the plurality of substrates 106-1, 106-2, . . . , 106-6, and facilitates the dissipation of heat from the same. External surfaces 116 of the heatsink member 108 form a plurality of external mounting surfaces, whereby each of the plurality of substrates 106-1, 106-2, . . . , 106-6 is mounted to a respective one of the external mounting surfaces 116 of the heatsink member 108. Each of the plurality of substrates 106-1, 106-2, . . . , 106-6 are configured to produce a forward light cone or a directional light by converting energy to optical photons. The forward light cone, directional light, and/or light forward manifests as a column of light traveling away from each of the plurality of substrates 106-1, 106-2, . . . , 106-6. The plurality of substrates 106-1, 106-2, . . . , 106-6 disposed around the perimeter of the heatsink member 108 result, in some embodiments, in more evenly/uniformly distributed light within a given area illuminated by the lighting device 100. Moreover, such light distribution may be understood to be substantially omnidirectional. Of course, a given external mounting surface may, and in some embodiments does, include two or more substrates and is not limited to one as shown in FIG. 2A.

A substrate of the plurality of substrates 106-1, 106-2, . . . , 106-6 may, and in some embodiments does, include a substrate panel made of a substrate material, such as but not limited to a printed circuit board (PCB), a flexible polymer substrate material, and so on, and one or more solid state light sources, such as but not limited to solid state light sources 118. In some embodiments, each of the one or more solid state light sources includes one or more dies, wherein each die is a solid-state semiconductor integrated circuit capable of converting electrical current to optical photons. To this end, each of the plurality of substrates 106-1, 106-2, . . . , 106-6, in some embodiments, essentially provides a lighting array, depending on the configuration of the plurality of substrates 106-1, 106-2, . . . , 106-6. In some embodiments, the OMS are implemented with metal core PCBs (MCPCBs). The metal core is formed from, for example but not limited to, aluminum, copper, or other suitable metal core configured to assist in dissipating heat generated by the solid state light source(s) and associated circuitry when the lighting device 100 is lit. The OMS are electrically coupled to the power supply circuit. In some embodiments, the OMS are electrically coupled in series, with a first substrate electrically coupled to a positive or negative terminal of terminals 112 of the power supply circuit, and a last substrate is electrically coupled to the other of the positive or negative terminal of the terminals 112. As should be appreciated, the OMS, in some embodiments, are coupled in parallel, and in some embodiments, a combination of series and parallel, depending on a desired configuration. As generally referred to herein, a terminal refers to a point at which a conductor from an electrical component comes to an end and provides a point of connection to other circuitry. Thus, a terminal in some embodiments is simply the end of a wire (such as shown in FIG. 2A) and in some embodiments is fitted with a connector, fastener, or other suitable member.

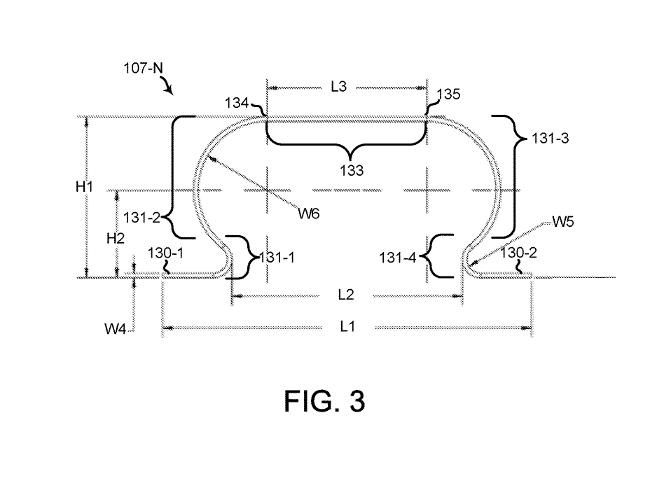

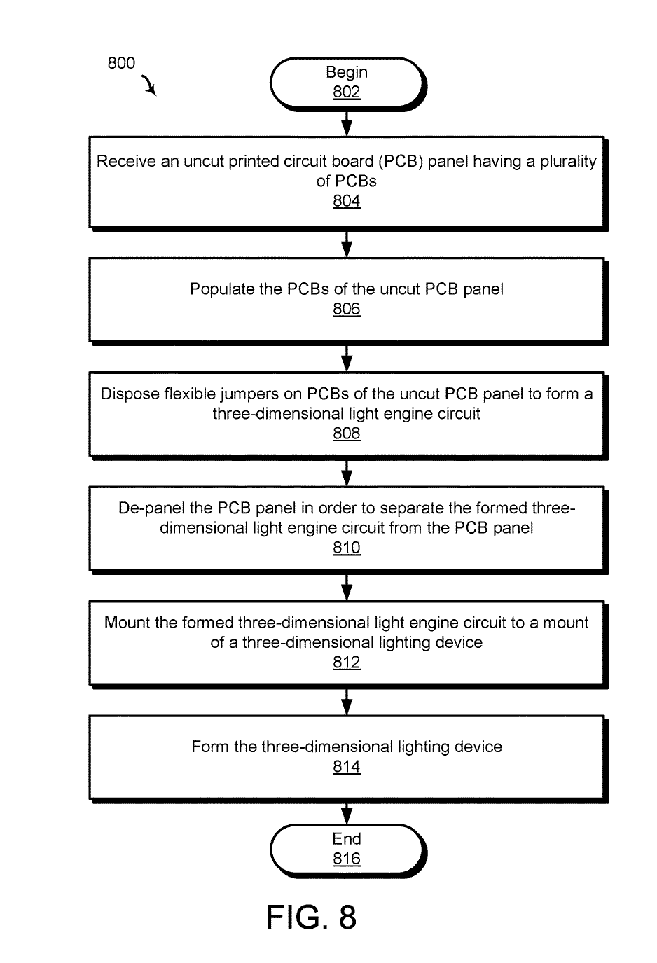

At least one of the OMS is electrically coupled to an adjacent substrate by a flexible jumper, such as one of the flexible jumpers 107-1, 107-2, . . . , 107-5. The flexible jumpers 107-1, 107-2, . . . , 107-5 are more easily seen in the top view of FIG. 2A that is shown in FIG. 2B. In some embodiments, the flexible jumpers 107-1, 107-2, . . . , 107-5 are surface mount device (SMD) jumpers. SMD jumpers are also sometimes referred to as surface mount technology (SMT) jumpers or surface mounted interconnect (SMI). SMD jumpers are able to electrically couple substrates disposed at two different angles because of their ability to “flex” or bend, and are able to accommodate up to at least 180 degrees of separation between adjacent substrates, for example. SMD jumpers are also able to be used in automated manufacturing schemes. As discussed further below with reference to FIG. 8, in some embodiments, this allows for high-volume, automated manufacturing of the lighting device 100. For example, in some embodiments, once placed using such automated process, reflow soldering processes is used to weld an SMD jumper. The flexible jumpers 107-1, 107-2, . . . , 107-5 are discussed in greater detail below with reference to FIGS. 3-7.

As also discussed below, the positioning of the OMS impacts whether the flexible jumpers 107-1, 107-2, . . . , 107-5 are within predefined tolerances. Thus, in some embodiments, the lighting device 100 includes mechanical members (or stops) that assist in ensuring substrates are substantially mounted at a predefined position, and remain at that predefined position after manufacture. For example, in some embodiments and as shown in FIG. 2A, the heatsink member 108 includes longitudinal stops 150, or guides, that are disposed on the external mounting surfaces of the heatsink member 108, and more particularly those external mounting surfaces used to mount vertically-mounted substrates in the OMS. Each longitudinal stop 150, in some embodiments, is spaced at a width W, with the width W being slightly greater than a width of a corresponding one or more of the OMS. Likewise, in some embodiments, and as also shown in FIG. 2A, the heatsink member 108 includes a ledge 151, or lateral stop, which supports one or more of the OMS. Thus, the longitudinal stops 150 and/or the lateral stops 151 are used, in some embodiments, to ensure proper positioning of each of the OMS when being attached during manufacturing. Further, the longitudinal stops 150 and/or the lateral stops 151, in some embodiments, minimize or otherwise mitigate movement of one or more of the OMS after formation of the lighting device 100. In some embodiments, a top surface 120 of the heatsink member 108 also includes one or more stops 152, or guides, that, in some embodiments, ensure one or more of the OMS mounted thereon are located at a predefined position. As should be appreciated, the particular geometries and location of stops on the heatsink member 108 varies and are not necessarily limited to the geometries shown in FIG. 2A. Moreover, in some embodiments, one or more stops are formed from the heatsink member 108 as an integral member, and in some embodiments, one or more stops are separate members disposed thereon, and in some embodiments, both.

Turning back to FIG. 2B, an elevation, or top, view of FIG. 2A is shown. As is seen, the OMS collectively form a light engine circuit and are disposed on the heatsink member 108 such that the light engine circuit essentially “wraps” around the external mounting surfaces of the heatsink member 108. Further, each of the OMS mounted in a vertical orientation (e.g., the substrates 106-1, 106-2, . . . , 106-5) face different directions. As also shown, each vertically-mounted substrate 106-1, 106-2, . . . , 106-5 is angled at about angle θ, which in FIG. 2A is about 110, though of course other angles are apparent in light of this disclosure. The substrate 106-6 is mounted horizontally on the top surface 120 of the heatsink member 108. Thus, the lighting device 100 provides substantially omnidirectional illumination in a given area based on the respective direction each of the OMS faces. As should be appreciated, the lighting device 100 in some embodiments includes a number of substrates that is different than the six substrates shown in FIGS. 2A and 2B, and thus embodiments are not limited to the six substrates illustrated therein.

As discussed above, in some embodiments, the lighting device 100 uses flexible jumpers (such as the flexible jumpers 1071-1, 107-2, . . . , 107-5 shown in FIGS. 2A and 2B0, or interconnects, to provide electrical coupling between each of the OMS. However, flexible jumpers such as SMD jumpers, in some embodiments, include exposed metallic or otherwise conductive surfaces. In a more general sense, SMD jumpers can essentially form bare-metal interconnects that can short or otherwise interact electrically with adjacent exposed conductive surfaces, e.g., through an electrical arc. Lighting standards such as the IEC60598-1 titled “Luminares—Part 1: General requirements and tests” published on May 26, 2014, requires that such exposed conductive surfaces maintain a minimum distance (e.g., creepage distance) from adjacent conductive elements relative to a RMS working voltage for a given luminaire/lighting device. For example, lighting devices that seek to operate at an RMS working voltage of about 150 volts must maintain at least 1.4 mm of distance between any two exposed electrically conductive elements.

Turning to FIG. 3, a flexible jumper 107-N suitable for use in the lighting device 100 of FIGS. 1-2B is shown. The flexible jumper 107-N has a generally “omega” shape, with the general omega shape being defined by a first end that forms a base 130-1, the base 130-1 having a portion that extends upwards to form a first arcuate region 131-1, followed by a portion that curves in an opposite direction to form a second arcuate region 131-2, where the first arcuate region 131-1 is about ¼ the length of the second arcuate region 131-2. The second arcuate region 131-2 then meets a first end 134 of a top region 133, with the top region 133 extending longitudinally along a path from the first end 134 to a second end 135, the path being substantially parallel to a path that the base 130-1 extends, and a length of the top portion L3 being about equal to a combined length H1 of the first arcuate region 131-1 and the second arcuate region 132-2. The second end 135 of the top region 133 then meets a third arcuate region 131-3, with the third arcuate region extending downwards in a first direction to a fourth arcuate region 131-4, with the fourth arcuate region 131-4 extending downward in a second direction, the second direction being substantially opposite the first direction. The fourth arcuate region 131-4 then continues to a second end 130-2 or base. Stated differently, the omega shape can include a first plurality of arcuate regions (e.g., 131-1 and 131-2, or 131-3 and 131-4) that extend from a first base portion (e.g., 130-1 or 130-2) to a first end (134 or 135) of a top portion 133, and a second plurality of arcuate regions (e.g., the other of 131-1 and 131-2 or 131-3 and 131-4) that extend from a second base portion (the other of 130-1 or 130-2) to a second end (the other of 134 or 135) of the top portion 133.

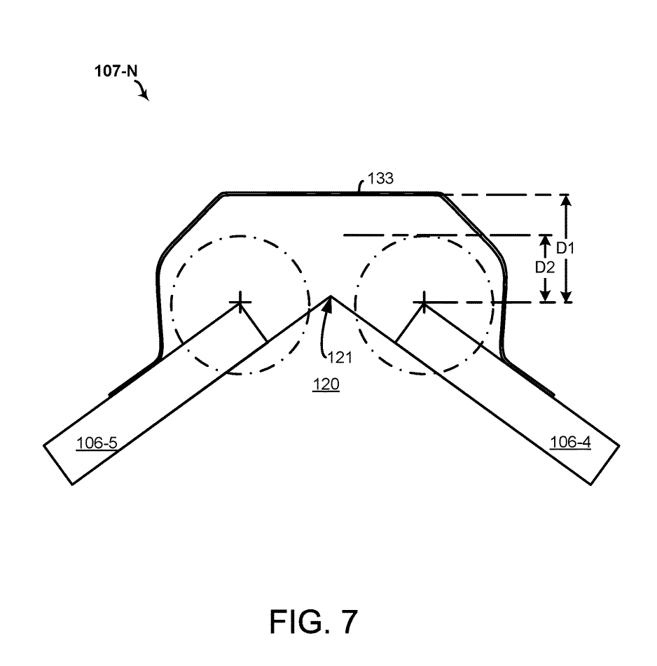

In some embodiments, the flexible jumper 107-N comprises an SMD jumper having an overall length L1 of about 8.0 mm, and an overall height H1 of about 3.50 mm, though of course other sizes are possible. Each of the first plurality of arcuate regions 131-1 and 131-2 and the second plurality of arcuate regions 131-3 and 131-4 may, and in some embodiments do, include a midpoint height H2, which in some embodiments is about 1.8 mm. The length L3 of the top portion 133, in some embodiments, is about 3.5 mm. The first and second base portions 130-1 and 130-2, in some embodiments, are separated by a length L2, which in some embodiments is about 5.0 mm. Each of the first base portion 130-1 and the second base portion 130-2, in some embodiments, include a width W4, which in some embodiments is about 0.1 mm, and a cross-wise width W5, which in some embodiments is about 0.30 mm. Likewise, the first plurality of arcuate regions 131-1 and 131-2 and the second plurality of arcuate regions 131-3 and 131-4 and top portion 133, in some embodiments, include the same width W4. In some embodiments, the first plurality of arcuate regions 131-1 and 131-2 and the second plurality of arcuate regions 131-3 and 131-4 and the top portion 133 also include a crosswise width W6, which in some embodiments is about 0.30 mm to 1.50 mm. As should be appreciated, the crosswise width of the flexible jumper 107-N, in some embodiments, tapers, for example, such that the first base portion 130-1 and the second base portion 130-2 have a first width W5, and the first plurality of arcuate regions 131-1 and 131-2 and the second plurality of arcuate regions 131-3 and 131-4 and the top portion 133 have a second width W6, with the first width W5 being less than the second width W6. The particular shape and geometries of the flexible jumper 107-N varies depending on a desired configuration and is not necessarily limited to what is shown in, and described in connection with, FIG. 3. For example, in some embodiments, other shapes and geometries are suitable, such as the double-bend shape of a flexible jumper 107-N shown in FIG. 7.

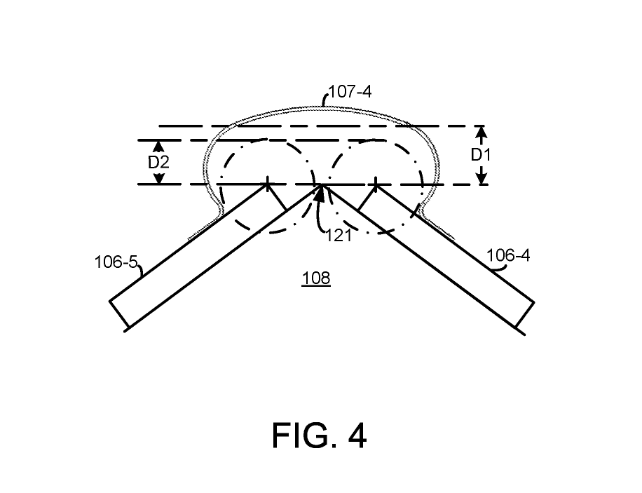

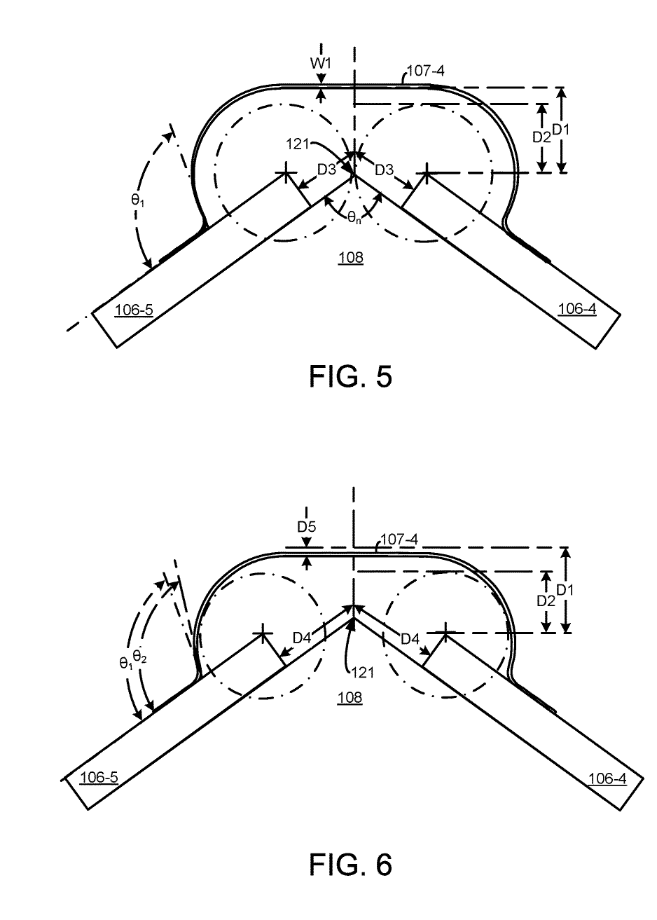

Turning to FIG. 4, a top-down perspective view illustrates a flexible jumper device 107-4 with a first end and a second end coupled, respectively, to a first substrate 106-4 and a second substrate 106-5. As should be appreciated, FIG. 4 is illustrated in a highly simplified manner. In some embodiments, surfaces of the heatsink member 108 of the lighting device 100 of FIGS. 1-2B are conductive, and thus, must be physically separated from the flexible jumper 107-4 by a predefined distance to comport with lighting standards, such as the IEC60598-1 standard discussed above. The flexible jumper 107-4 has a generally omega shape such that it “bows” out in a manner that causes its surfaces to extend away from a corner surface 121 of the heatsink member 108. To this end, the flexible jumper 107-4 is configured with geometries to ensure that a particular threshold distance D2 is maintained, even in the event of longitudinal positional deviations between adjacent substrates 106-4, 106-5, as discussed further below in greater detail with regard to FIGS. 5 and 6. For example, in some embodiments, the lighting device 100 is configured to operate with a working RMS voltage of 150 volts. In such embodiments, the IEC60598-1 stipulates a distance, also known as a creepage distance, of no less than 1.4 mm between surfaces of the flexible jumper 107-4 and the surfaces of the heatsink member 108. The particular surfaces of concern in this example include the corner surface 121 of the heatsink member 108 as it is the closest exposed surface relative to the flexible jumper 107-4. However, as should be appreciated, surfaces of concern include any surface that is conductive and may be subject to creepage distances as governed by the IEC60598-1, or other applicable standards. For example, additional surfaces of concern can include the substrates 106-4 and 106-5, as they may comprise a metal core PCB, which also must be kept the predefined particular threshold distance D2 from surfaces of the flexible jumper 107-4. Continuing this example, consider the particular threshold distance D2 to represent 1.4 mm, while a distance D1 represents 1.6 mm. The particular geometry of the flexible jumper 107-4 enables surfaces of the same to extend far enough away, e.g., to the distance D1 of 1.6 mm, which exceeds the required distance of 1.4 mm from the aforementioned surfaces of concern, and thus, is well within tolerance when the lighting device 100 operates with an RMS working voltage of up to about 150 volts. As should be appreciated, the geometries of the flexible jumper 107-4, in some embodiments, enable a range of tolerances to be observed and is equally applicable to standards requiring different distances. For example, in some embodiments, the flexible jumpers accommodate distances required for RMS working voltages greater than 150, such as voltages ranging between 250 to 1000 volts, which by the IEC60598-1 standard requires distances of 1.7 mm to 5.5 mm, respectively. As should be appreciated, lesser RMS working voltages requiring a smaller distance than 1.4 mm, such as 50 volts@0.6 mm, are also within the scope of this disclosure.

The flexible jumper devices disclosed herein, such as the flexible jumper 107-4, allow each substrate to be positioned at various distances from a corner surface 121 of the heatsink member 108 while still ensuring that the surfaces of the flexible jumper remain within tolerance, e.g., a predefined distance away from surfaces of concern such as a metal core of a substrate material of a given substrate and a corner surface 121 of the heatsink member 108, for example. This particular aspect of the flexible jumpers may be generally understood as “flex” but in a more technical sense is the ability of the flexible jumpers to bend and accommodate substrate disposed at two different angles as well as the particular distance separating the two substrates. The maximum amount of flex for each flexible jumper, e.g., the maximum angles and separation differences between mounting points on adjacent substrates prior to causing a surface of each flexible jumper to be outside of predefined tolerances, is thus at least based on the geometry and material composition chosen for each of the flexible jumpers, and may be configurable. It should also be appreciated that the particular material composition of each flexible jumper is important to ensure a nominal amount of longitudinal displacement occurs such that two substrates interconnected by a given flexible jumper stay relatively fixed in place. For example, two adjacent and interconnected substrates, in some embodiments, may be “pulled” towards one another if the particular fixation approach holding them against the heatsink member 108 is overcome by the spring-like tension/strain introduced by a flexible jumper. For instance, in some embodiments, some adhesives such as glue and double-sided thermal tape are particularly well suited for affixing substrates to the heatsink member 108, but may not be able to hold substrates at a fixed position when the flexible jumper introduces a bias force. On the other hand, the particular material composition of the flexible jumper should not allow too much flex, as the flexible jumper may become deformed as a result of, for example, forces applied during manufacturing of the lighting device 100. Further considerations include material costs, as certain material composition may lend itself well to the various parameters discussed above but may be cost-prohibitive when mass producing the lighting device 100. Thus the material composition of the flexible jumpers, such as the flexible jumpers 107-1, 107-2, . . . , 107-5 of FIGS. 1A-2B, may be and in some embodiments are selected based on the particular design requirements for the lighting device 100, as well as based on factors such as cost per flexible jumper and manufacturing complexity. In some embodiments, the flexible jumpers are formed from a first material and coated by a second material. For instance, some example coatings include tin (Sn) and nickel (Ni), although other coating materials are apparent in light of this disclosure. In some embodiments, the flexible jumpers are formed from, for example, steel (e.g., SUS304), copper, nickel, or any alloy thereof. Numerous other metals/alloys should be apparent in light of this disclosure, such as but not limited to beryllium-copper alloy, copper-nickel alloy, and bronze. In addition, the thickness of the material, e.g., a width W1 shown in FIG. 5, varies depending on a desired configuration. For the purpose of providing some specific, non-limiting values, the following table assumes a nominal thickness width W1 of about 0.1 mm to 2 mm and a nominal width of about 1.5 mm. A non-exhaustive, non-limiting list of suitable material compositions for use with the present disclosure are provided in Table 1 below for reference.

TABLE 1

| | | | | Tensile |
|---|---|---|---|---|
| | | | Modulus of | Strength |
| Material | Hardness | Coating/ | Elasticity, | (N/mm²) |
| Composition | (Grading) | Plating | (E, GPa) | (JIS) |
| SUS304 | H¼ | No Plating | 193 GPa | 650 |
| SUS304 | H¼ | Ni | 193 GPa | 650 |
| SUS304 | H¼ | Tin | 193 GPa | 650 |
| BeCU | H½ | No Plating | 125-130 | 585-690 |
| BeCU | H½ | Ni | 125-130 | 585-690 |
| BeCU | H½ | Tin | 125-130 | 585-690 |
| Copper- | H½ | No Plating | 125 | 440-570 |
| Nickel Alloy | | | | |
| Copper- | Full- | No Plating | 125 | 630-735 |
| Nickel Alloy | Hard | | | |
| SUS304 | H¼ | Ni | 193 GPa | 650 |
| SUS304 | H½ | Ni | 193 Gpa | 780 |
| Bronze | H¼ | No Plating | 103 | 490-610 |
| 0.2 mm | | | | |
| thickness | | | | |
| Brass 0.2 mm | H¼ | No Plating | 106 | 355-440 |
| thickness | | | | |
| BeCU | H¼ | No Plating | 125-130 | 585-690 |
| Copper | H¼ | No Plating | 117 | 220 |
| 0.2 mm | | | | |
| thickness | | | | |
| Bronze | H½ | Ni | 103 | 490-610 |
| 0.2 mm | | | | |
| thickness | | | | |
| Brass 0.2 mm | H½ | Ni | 106 | 355-440 |
| thickness | | | | |
| BeCU ¼ | H¼ | Ni | 125-130 | 585-690 |
| hard | | | | |

As shown above, different material compositions may be selected to achieve a desired rigidity/elasticity for the flexible jumpers. The result of such rigidity/elasticity may be better understood by way of illustration. Consider FIG. 5, which shows the substrate 106-4 and the substrate 106-5 disposed at a distance D3 relative to the corner surface 121 of the heatsink member 108, and disposed at an angle θₙ of about 110 degrees relative to each other. The flexible jumper 107-4 extends from the surface of the substrates 106-4 and 106-5 at an angle θ1. The flexible jumper 107-4 may assert a spring-like bias on the substrates 106-4 and 106-5 based on the distance D3, which can cause partial deformation illustrated by the angle θ₁. Therefore, increasing the distance D3 (such as shown in FIG. 5) can result in an increased bias applied by the flexible jumper 107-4. Stated differently, the longitudinal placement of the substrates 106-4 and 106-5 can increase the tension of the flexible jumper 107-4 and cause the same to further deform. For example, as shown in FIG. 6, the substrates 106-4 and 106-5 are disposed at a distance D4, with the distance D4 being greater than the distance D3 of FIG. 5. Thus, the flexible jumper 107-4 extends from the surface of the substrates 106-4 and 106-5 at an angle θ₂, with the angle θ₂ causing a slightly more aggressive/steeper curvature of the flexible jumper 107-4. For reference, FIG. 6 also shows the angle θ₁ of FIG. 5 juxtaposed next to the angle θ₂ for the purpose of contrast. As should be appreciated, this more aggressive curvature also results in the upper surface of the flexible jumper 107-4 vertically shifting/offsetting towards the heatsink member 108 by a distance D5. Recall that in a previous example with an RMS working voltage of up to about 150V, the distance D1 was about 1.6 mm and the minimum required creepage distance was about 1.4 mm. Assuming a similar configuration for the purpose of illustration, the vertical offset represented by the distance D5 may, and in some embodiments does, reduce the overall distance from the flexible jumper 107-4 to the heatsink member 108, and thus brings the flexible jumper 107-4 closer to the allowed tolerance of 1.4 mm. As shown, the flexible jumper 107-4 remains within tolerance, but further deformation of the same, e.g., based on longitudinal movement of the substrates 106-4 and 106-5 away from each other, can result in the flexible jumper 107-4 being out of tolerance. The maximum distances between the substrates 106-4 and 106-5 may be, and in some embodiments is, governed at least in part by the particular geometries and material composition of a given flexible jumper. These particular parameters may be, and in some embodiments are, optimized to accommodate the range of potential distances between adjacent substrates that may result during manufacture of the lighting device 100.

Although specific embodiments and scenarios disclosed herein illustrate and describe a so-called “omega” shape flexible jumper, other geometries and configurations are within the scope of this disclosure. For example, FIG. 7 illustrates a so-called “double-bend” flexible jumper 107-N. As shown in FIG. 7, the double-bend flexible jumper 107-N includes sides that extend upward and bend prior to meeting a top surface 133. Thus, numerous other geometries and configurations of the flexible jumper 107-N should be apparent and are also within the scope of this disclosure.

A flowchart of a method 800 is depicted in FIG. 8. In some embodiments, rectangular elements are herein denoted “processing blocks” and represent computer software instructions or groups of instructions. In some embodiments, diamond shaped elements are herein denoted “decision blocks” and represent computer software instructions, or groups of instructions which affect the execution of the computer software instructions represented by the processing blocks. Alternatively, the processing and decision blocks represent steps performed by functionally equivalent circuits, such as but not limited to a microprocessor circuit or an application specific integrated circuit (ASIC). The flowchart does not depict the syntax of any particular programming language. Rather, in some embodiments, the flowchart illustrates the functional information one of ordinary skill in the art requires to fabricate circuits or to generate computer software to perform the processing required in accordance with the present invention. It should be noted that many routine program elements, such as initialization of loops and variables and the use of temporary variables, are not shown. It will be appreciated by those of ordinary skill in the art that unless otherwise indicated herein, the particular sequence of steps described is illustrative only and can be varied without departing from the spirit of the invention. Thus, unless otherwise stated the steps described below are unordered meaning that, when possible, the steps can be performed in any convenient or desirable order.

Further, while FIG. 8 illustrates various operations and/or steps, it is to be understood that not all of the operations depicted in FIG. 8 are necessary for other embodiments to function. Indeed, it is fully contemplated herein that in other embodiments, the operations depicted in FIG. 8, and/or other operations described herein, may be combined in a manner not specifically shown in any of the drawings, but still fully consistent with the present disclosure. Thus, claims directed to features and/or operations that are not exactly shown in one drawing are deemed within the scope and content of the present disclosure.

The method 800 includes various steps, which in some embodiments, are performed at least in part by an automated process, such as by SMT (surface mount technology) component placement systems, sometimes referred to as pick-and-place machines or P&Ps. Such SMT component systems are particularly well suited for high-speed, high-precision placing of a broad range of components onto substrates including, for example, SMD jumpers, capacitors, resistors, integrated circuits, and the like. The method 800 begins, step 802, and receives a printed circuit board (PCB) panel (also referred to throughout as a substrate panel) having a plurality of panelized PCBs (also referred to throughout as substrates), step 804. An example PCB panel 140 is shown in FIG. 9. As shown, the PCB panel 140 includes an M×N array of PCBs 136 with de-panelization regions 139 located between adjacent PCBs. As should be appreciated, the PCBs may be, and in some embodiments are, patterned and populated such that pads, traces, and electrical components are disposed thereon prior to receiving the PCB panel 140. However, for purposes of clarity and practicality, the PCB panel 140 is shown in FIG. 9 in a highly simplified form. Thus, the PCB panel 140 of FIG. 9, in some embodiments, is at least partially populated and may include, for example, fiducial markers, blank regions, tab-routing regions, tooling marks, and so on. The total number of rows and columns of PCBs may vary depending on a desired panel configuration, and the particular configuration shown in FIG. 9 should not be construed as limiting. The de-panelization regions 139, in some embodiments, include, for instance, V-scored areas that allow for de-panelization using a v-groove cuffing wheel. Other de-panelization schemes are also within the scope of this disclosure and include any suitable method that allows for PCBs to be singulated.

The M×N array of PCBs 136, in some embodiments, comprise metal core PCBs (MCPCBs) as previously discussed with reference to FIG. 1, or any other suitable type of substrate capable of supporting electrical components and circuits of the lighting device 100. The particular dimension of each PCB of the PCB panel 140 may vary depending on a desired configuration. However, for the purpose of providing some specific non-limiting example dimensions, in some embodiments, a width W of each PCB is about 10 mm, a length L is about 10 mm, and a height H is about 1.5 mm. As should be appreciated, the PCBs are necessarily square/rectangular in shape, and in some embodiments, are formed as other regular or irregular shapes.

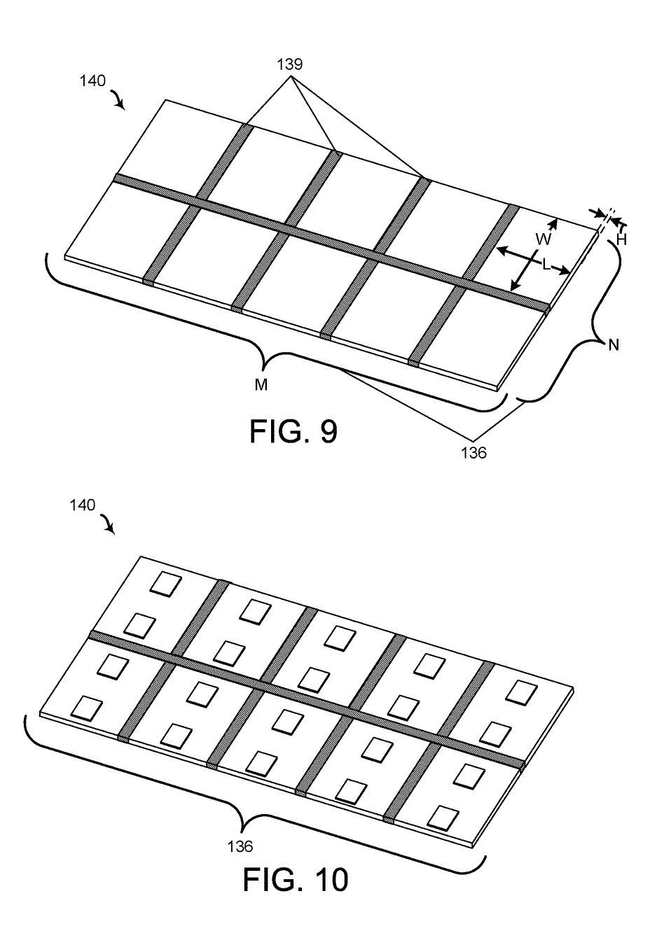

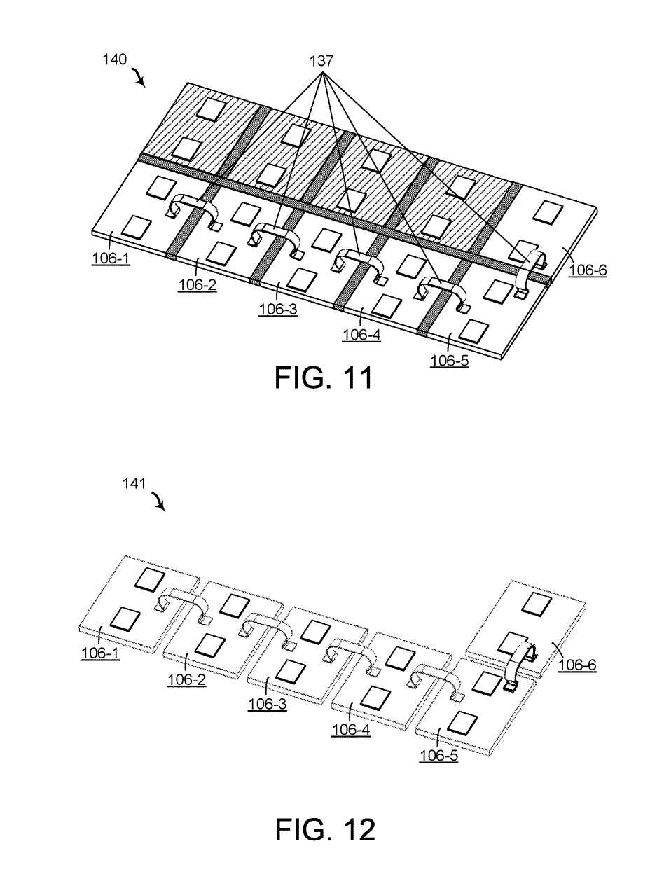

Returning to FIG. 8, the plurality of PCBs of the uncut PCB panel 140 are populated, step 806. In some embodiments, one or more solid state light sources (e.g., the solid state light sources 118 of FIG. 1) are deposited on each of the PCBs 136, such as shown in FIG. 10. In some embodiments, the one or more solid state light sources are electrically coupled to associated circuitry via, for example, reflow, wave soldering, or other soldering/welding techniques. A plurality of flexible jumpers 137 are disposed onto PCBs of the panel of PCBs 140, step 808, to form at least one light engine circuit, which in some embodiments is a three-dimensional light engine circuit, as described throughout. For example, as shown in FIG. 11, a plurality of flexible jumpers 137 is deposited such that a light engine circuit is formed. Deposition of the plurality of flexible jumpers 137, in some embodiments, for example, uses a SMT component placement system, or pick-and-place, whereby each of the flexible jumpers 137 is placed accurately/precisely at predefined positions with a tolerance of ±0.05 mm or better. The flexible jumpers 137 in such embodiments are then fixedly and electrically attached via, for example, reflow or wave soldering approaches. Thus, as shown, the OMS are formed and collectively define a light engine circuit. As should be appreciated, any number of light engine circuits may be, and in some embodiments are, formed, and the particular embodiment shown in FIG. 11 should not be construed as limiting. For example, other PCBs (e.g., shown as shaded) may be used to form additional light engine circuits. Thus, each PCB panel 140 may be, and in some embodiments are, used to construct N number of light engine circuits. Moreover, each light engine circuit, in some embodiments, includes more or fewer PCBs, depending on a desired configuration for each light engine circuit.

Returning again to FIG. 8, the PCB panel 140 is de-paneled to separate the formed light engine circuit from the same, step 810. The PCB panel 140, in some embodiments, is de-paneled based on application of mechanical force, cutting, or other approaches that cause each PCB to be separated from the PCB panel 140 and from other adjacent PCBs. For example, as shown in FIG. 12, a formed and separated light engine circuit 141 is shown. Although the formed and separated light engine 141 is shown in a series circuit configuration, as described throughout, other configurations are within the scope of this disclosure. For example, the formed and separated light engine circuit 141, in some embodiments, is formed as a parallel circuit with minor modification to the method 800. Moreover, the formed and separated light engine circuit 141, in some embodiments, is formed with both series circuits and parallel circuits depending on a desired application.

Returning to FIG. 8, the formed light engine circuit 141 is mounted to a mount of a three-dimensional lighting device, such as the lighting device 100, step 812. For example, a tape, adhesive, or other fastening mechanism is used to fixedly attach each of the OMS to external mounting surfaces of the heatsink member 108. In some embodiments, the tape or adhesive is a thermally conductive with low thermal resistance configured to pass heat from a substrate to, for example, the heatsink member 108. Finally, formation of the three-dimensional lighting device is completed, step 814. For example, in some embodiments, the method 800 forms the lighting device 100 by electrically coupling a first substrate (e.g., the substrate 106-1) to a positive or negative terminal 112 of the lighting device 100 and a last substrate assembly (e.g., the substrate 106-6) to the other of the positive or negative terminal 112. Formation, in some embodiments, also includes fixedly attaching the optical system 110 and/or other components to complete formation of the lighting device 100.

The methods and systems described herein are not limited to a particular hardware or software configuration, and may find applicability in many computing or processing environments. The methods and systems may be implemented in hardware or software, or a combination of hardware and software. The methods and systems may be implemented in one or more computer programs, where a computer program may be understood to include one or more processor executable instructions. The computer program(s) may execute on one or more programmable processors, and may be stored on one or more storage medium readable by the processor (including volatile and non-volatile memory and/or storage elements), one or more input devices, and/or one or more output devices. The processor thus may access one or more input devices to obtain input data, and may access one or more output devices to communicate output data. The input and/or output devices may include one or more of the following: Random Access Memory (RAM), Redundant Array of Independent Disks (RAID), floppy drive, CD, DVD, magnetic disk, internal hard drive, external hard drive, memory stick, or other storage device capable of being accessed by a processor as provided herein, where such aforementioned examples are not exhaustive, and are for illustration and not limitation.

The computer program(s) may be implemented using one or more high level procedural or object-oriented programming languages to communicate with a computer system; however, the program(s) may be implemented in assembly or machine language, if desired. The language may be compiled or interpreted.

As provided herein, the processor(s) may thus be embedded in one or more devices that may be operated independently or together in a networked environment, where the network may include, for example, a Local Area Network (LAN), wide area network (WAN), and/or may include an intranet and/or the internet and/or another network. The network(s) may be wired or wireless or a combination thereof and may use one or more communications protocols to facilitate communications between the different processors. The processors may be configured for distributed processing and may utilize, in some embodiments, a client-server model as needed. Accordingly, the methods and systems may utilize multiple processors and/or processor devices, and the processor instructions may be divided amongst such single- or multiple-processor/devices.

The device(s) or computer systems that integrate with the processor(s) may include, for example, a personal computer(s), workstation(s) (e.g., Sun, HP), personal digital assistant(s) (PDA(s)), handheld device(s) such as cellular telephone(s) or smart cellphone(s), laptop(s), handheld computer(s), or another device(s) capable of being integrated with a processor(s) that may operate as provided herein. Accordingly, the devices provided herein are not exhaustive and are provided for illustration and not limitation.

References to “a microprocessor” and “a processor”, or “the microprocessor” and “the processor,” may be understood to include one or more microprocessors that may communicate in a stand-alone and/or a distributed environment(s), and may thus be configured to communicate via wired or wireless communications with other processors, where such one or more processor may be configured to operate on one or more processor-controlled devices that may be similar or different devices. Use of such “microprocessor” or “processor” terminology may thus also be understood to include a central processing unit, an arithmetic logic unit, an application-specific integrated circuit (IC), and/or a task engine, with such examples provided for illustration and not limitation.

Furthermore, references to memory, unless otherwise specified, may include one or more processor-readable and accessible memory elements and/or components that may be internal to the processor-controlled device, external to the processor-controlled device, and/or may be accessed via a wired or wireless network using a variety of communications protocols, and unless otherwise specified, may be arranged to include a combination of external and internal memory devices, where such memory may be contiguous and/or partitioned based on the application. Accordingly, references to a database may be understood to include one or more memory associations, where such references may include commercially available database products (e.g., SQL, Informix, Oracle) and also proprietary databases, and may also include other structures for associating memory such as links, queues, graphs, trees, with such structures provided for illustration and not limitation.

References to a network, unless provided otherwise, may include one or more intranets and/or the internet. References herein to microprocessor instructions or microprocessor-executable instructions, in accordance with the above, may be understood to include programmable hardware.

Unless otherwise stated, use of the word “substantially” may be construed to include a precise relationship, condition, arrangement, orientation, and/or other characteristic, and deviations thereof as understood by one of ordinary skill in the art, to the extent that such deviations do not materially affect the disclosed methods and systems.

Throughout the entirety of the present disclosure, use of the articles “a” and/or “an” and/or “the” to modify a noun may be understood to be used for convenience and to include one, or more than one, of the modified noun, unless otherwise specifically stated. The terms “comprising”, “including” and “having” are intended to be inclusive and mean that there may be additional elements other than the listed elements.

Elements, components, modules, and/or parts thereof that are described and/or otherwise portrayed through the figures to communicate with, be associated with, and/or be based on, something else, may be understood to so communicate, be associated with, and or be based on in a direct and/or indirect manner, unless otherwise stipulated herein.

Although the methods and systems have been described relative to a specific embodiment thereof, they are not so limited. Obviously many modifications and variations may become apparent in light of the above teachings. Many additional changes in the details, materials, and arrangement of parts, herein described and illustrated, may be made by those skilled in the art.

What is claimed is:

1. A method of forming a lighting device, the method comprising:
populating a substrate panel with a plurality of solid state light sources, wherein the substrate panel comprises a plurality of substrates configured to be de-panelized and collectively form a light engine circuit;
depositing a plurality of surface mount device (SMD) jumpers on the substrate panel to electrically couple at least two substrates of the plurality of substrates;
de-paneling the at least two substrates from the substrate panel to form the light engine circuit; and
mounting the light engine circuit to a body portion of the lighting device by coupling the at least two substrates of the plurality of substrates to respective external mounting surfaces of the body portion.

2. The method of claim 1, wherein depositing comprises depositing a plurality of surface mount device (SMD) jumpers on the substrate panel to electrically couple at least two substrates of the plurality of substrates, wherein each of the at least two substrates comprise a printed circuit board including a metal core.

3. The method of claim 1, wherein depositing comprises depositing a plurality of surface mount device (SMD) jumpers on the substrate panel to electrically couple at least two substrates of the plurality of substrates, wherein the plurality of SMD jumpers comprise an alloy.

4. The method of claim 1, wherein depositing comprises depositing a plurality of surface mount device (SMD) jumpers on the substrate panel to electrically couple at least two substrates of the plurality of substrates, wherein the plurality of SMD jumpers comprise a generally omega shape.

5. The method of claim 1, wherein depositing the plurality of SMD jumpers further comprises using a surface mount technology (SMT) component placement system.

6. The method of claim 1, wherein mounting the light engine circuit to a body portion comprises:
mounting the light engine circuit to a body portion of the lighting device by coupling the at least two substrates of the plurality of substrates to respective external mounting surfaces of the body portion, wherein the body portion of the lighting device comprises a heatsink member, and wherein the mounting surfaces comprise at least three vertical mounting surfaces defined by the heatsink member.

7. The method of claim 1, wherein mounting the light engine circuit to the body portion of the lighting device comprises coupling the at least two substrates at differing angles, the differing angles causing each SMD jumper to bend to accommodate a difference in angles between adjacent substrates, and wherein each SMD jumper extends from the body portion of the lighting device to provide a clearance distance between surfaces of each SMD jumper and any exposed conductive surface of the lighting device.

8. The method of claim 7, wherein mounting the light engine circuit to the body portion of the lighting device comprises coupling the at least two substrates at differing angles, the differing angles causing each SMD jumper to bend to accommodate a difference in angles between adjacent substrates, and wherein each SMD jumper extends from the body portion of the lighting device to provide a clearance distance between surfaces of each SMD jumper and any exposed conductive surface of the lighting device, and wherein the clearance distance is at least 0.6 mm.

9. The method of claim 1, wherein mounting the light engine circuit further comprises using mechanical stops provided by the body portion to align each substrate of the at least two substrates.

10. A lighting device, comprising:
a body portion providing a plurality of external mounting surfaces; and
a plurality of substrates with at least one substrates coupled to each of the plurality of external mounting surfaces, each substrate comprising a solid state light source;
wherein each substrate is electrically coupled to an adjacent substrate via a surface mount device (SMD) jumper that provides electrical conductivity between each substrate and the adjacent substrate.

11. The lighting device of claim 10, wherein the body portion comprises a heatsink member and the plurality of external mounting surfaces are provided by the heatsink member.

12. The lighting device of claim 10, wherein each of the plurality of printed circuit boards comprise a printed circuit board including a metal core.

13. The lighting device of claim 10, wherein each SMD jumper comprises an alloy.

14. The lighting device of claim 10, wherein each SMD jumper comprises a generally omega shape.

15. The lighting device of claim 10, wherein each of the SMD jumpers provide a predefined clearance between surfaces of the SMD jumpers and any exposed conductive surface of the lighting device.

16. The lighting device of claim 15, wherein the predefined clearance is at least 0.6 mm, and wherein the exposed conductive surface of the lighting device comprises a surface of a metal heatsink member.

17. The lighting device of claim 10, wherein each SMD jumper includes a plurality of arcuate regions configured to extend conductive surfaces of each SMD jumper away from exposed conductive surfaces of the lighting device.

18. The lighting device of claim 10, wherein each of the plurality of substrates are electrically coupled in series.

19. A lighting device, comprising:
a body portion comprising a heatsink member, the heatsink member providing a plurality of external mounting surfaces, the plurality of external mounting surfaces including at least three vertical mounting surfaces that extend to a top mounting surface; and
a plurality of substrates, each substrate comprising a solid state light source, wherein at least one substrate of the plurality of substrates is coupled to each of the plurality of external mounting surfaces;
wherein each substrate is electrically coupled to an adjacent substrate via a surface mount device (SMD) jumper that provides electrical conductivity between each substrate and the adjacent substrate.

20. The lighting device of claim 19, wherein each SMD jumper extends away from any exposed conductive surface of the lighting device by a clearance distance.

21. The lighting device of claim 20, wherein the clearance distance is at least 1.4 mm.
